(19) United States
(12) Patent Application Publication
(10) Pub. No.: US 2026/0096386 A1
(43) Pub. Date: Apr. 2, 2026

(54) LOAD LOCK CHAMBER IMPROVEMENT

(71) Applicant: Applied Materials, Inc., Santa Clara, CA (US)

(72) Inventors: Srikanth V. RACHERLA, Fremont, CA (US); Makoto INAGAWA, Palo Alto, CA (US); Subhasish ROY, Bangalore (IN)

(21) Appl. No.: 19/302,814

(22) Filed: Aug. 18, 2025

Related U.S. Application Data
(60) Provisional application No. 63/701,077, filed on Sep. 30, 2024.

(51) Int. Cl. H01L 21/67

(52) U.S. Cl. CPC H10P 72/0466; H10P 72/0402

(57) ABSTRACT

A system for transferring a substrate from a high pressure area to a low pressure area is provided. The system includes a load lock chamber that includes: a chamber body disposed around an interior volume; a first substrate support; a first exhaust inlet; and a first baffle positioned between the first substrate support and the first exhaust inlet. The system further includes a first exhaust line fluidly coupled to the interior volume through the first exhaust inlet.

### CROSS REFERENCE TO RELATED APPLICATIONS

This application claims benefit of U.S. provisional patent application Ser. No. 63/701,077 filed Sep. 30, 2024, which is hereby incorporated herein by reference.

### BACKGROUND

### Field

The embodiments disclosed generally relate to load lock chambers that can improve the product quality of the substrates being transferred through the load lock chambers.

### Description of the Related Art

Load lock chambers are commonly used to transfer substrates (e.g., semiconductor substrates) between different environments, such as between an atmospheric pressure environment and a vacuum environment.

Despite efforts to make the environment inside the load lock chambers as clean as possible, particles can still accumulate inside of load lock chambers. For example, particles from a substrate can become airborne and stick to a component inside of the load lock chamber when the substrate is being transferred through load lock chamber. These particles can eventually land on subsequent substrates being transferred through the load lock chamber and lead to product quality issues for those subsequent substrates.

Accordingly, there is an ongoing need to reduce the number of particles inside load lock chambers.

### SUMMARY

In one embodiment, a system for transferring a substrate from a high pressure area to a low pressure area is provided. The system includes a load lock chamber that includes: a chamber body disposed around an interior volume; a first substrate support; a first exhaust inlet; and a first baffle positioned between the first substrate support and the first exhaust inlet. The system further includes a first exhaust line fluidly coupled to the interior volume through the first exhaust inlet.

In another embodiment, a system for transferring a substrate from a high pressure area to a low pressure area is provided, the system comprising: a load lock chamber comprising: a chamber body disposed around an interior volume; a first substrate support; a first exhaust inlet; and a first baffle positioned in the interior volume, the first baffle configured to redirect a gas flow into the first exhaust inlet; a first exhaust line fluidly coupled to the interior volume through the first exhaust inlet; a vacuum pump fluidly coupled to the first exhaust line; a heater configured to heat gas in the first exhaust line; and a controller configured to activate the heater to heat gas in the first exhaust line when the vacuum pump is reducing a pressure of the interior volume.

In another embodiment, a method of moving a substrate from a high pressure environment to a low pressure environment is provided, the method comprising: transferring a substrate into an interior volume of a load lock chamber when the interior volume of the load lock chamber is at a first pressure, wherein the substrate is positioned on a first substrate support in the interior volume, and a first exhaust line is fluidly coupled to the interior volume through a first exhaust inlet of the load lock chamber; reducing a pressure in the interior volume to a second pressure that is lower than the first pressure by exhausting gas from the interior volume through the first exhaust line when the substrate is positioned on the substrate support in the interior volume, the load lock chamber including a first baffle positioned between the first substrate support and the first exhaust inlet, wherein the first baffle redirects a gas flow into the first exhaust inlet as the pressure in the interior volume is reduced from the first pressure to the second pressure; and removing the substrate from the interior volume after the pressure of the interior volume is at the second pressure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 shows a side cross-sectional view of a processing system, according to one embodiment.

FIG. 2 shows a front view of a front surface of the first baffle from FIG. 1, according to one embodiment.

FIG. 3 is a process flow diagram of a method of transferring a substrate through the load lock chamber of FIG. 1 using the processing system of FIG. 1, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments provided in this disclosure generally relate to load lock chambers that can improve the product quality of the substrates being transferred through the load lock chambers. These embodiments of load lock chambers improve the product quality of the substrates being transferred through the load lock chambers by reducing the number of particles and number of large particles that are present in the interior volume of the corresponding load lock chamber.

This reduction is achieved in part by reducing the condensation occurring inside the load lock chamber and inside exhaust lines connected to the load lock chamber. Condensation can contribute to the formation of large particles. Thus, the reduction of condensation leads to lower concentrations of large particles and less large particles landing on the substrates in the load lock chamber. The reduction in condensation is achieved by using a baffle near the exhaust inlet for the load lock chamber and by using one or more heaters on the exhaust line. The baffles cause the pressure in the load lock chamber and the exhaust line to be more uniform as these pressures are quickly reduced to vacuum pressures during load lock chamber operation which removes areas of extreme low pressure that have the most condensation. The external fore line heater increases the temperature in the vacuum line which also leads to less condensation. Having more uniform pressure can also lead to less particle creation by reducing the number of particles that go airborne from a substrate in the load lock chamber.

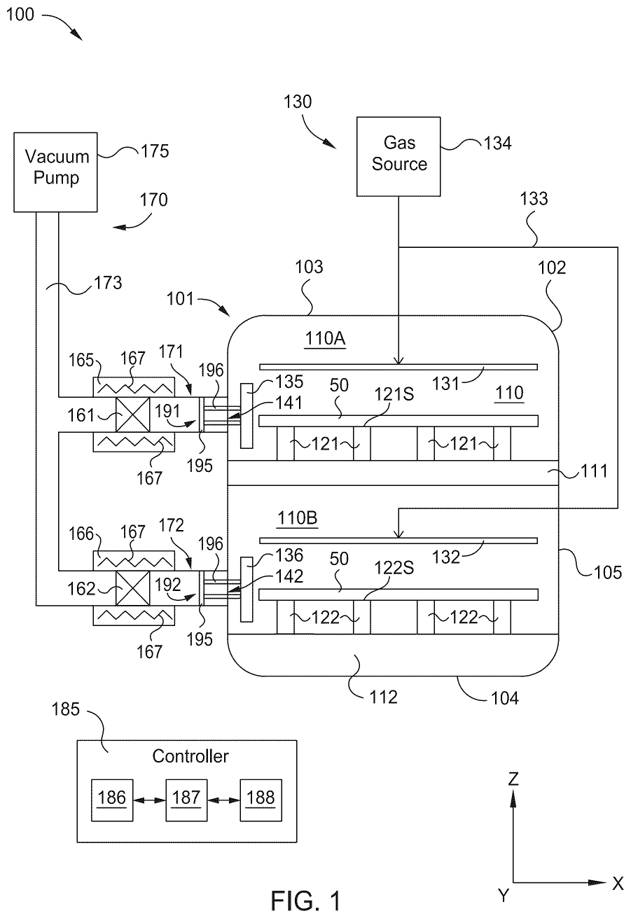

FIG. 1 shows a side cross-sectional view of a processing system 100, according to one embodiment. The processing system 100 includes a load lock chamber 101, a gas supply system 130, a vacuum exhaust system 170, and a controller 185. The load lock chamber 101 includes a chamber body 102 disposed around an interior volume 110. The chamber body 102 includes a top 103, a bottom 104, and one or more sidewalls 105 connecting the top 103 with the bottom 104. The load lock chamber 101 can include one or more ports (not shown), such as two slit valves configured to open to allow the transferring of one or more substrates 50 into and out of the interior volume 110 of the load lock chamber 101.

The load lock chamber 101 includes a first support 111 and a second support 112. A first plurality of standoffs 121 extend upward from the first support 111. The first plurality of standoffs 121 can also be referred to as a first substrate support 121. Each standoff 121 includes a substrate supporting surface 121S on which a substrate 50 can be positioned. A substrate 50 is shown positioned on the first plurality of standoffs 121.

Similarly, a second plurality of standoffs 122 extend upward from the second support 112. The second plurality of standoffs 122 can also be referred to as a second substrate support 122. Each standoff 122 includes a substrate supporting surface 122S on which a substrate 50 can be positioned. A substrate 50 is shown positioned on the second plurality of standoffs 122. The interior volume 110 includes a first portion 110A above the first support 111 and a second portion 110B below the first support 111 and above the second support 112. In some embodiments, which can be combined with other embodiments, the first portion 110A can be isolated from the second portion 110B, so that pressure changes in one portion 110A, 110B does not affect the pressure in the other portion 110A, 110B. In these embodiments, the first support 111 can isolate the first portion 110A of the interior volume 110 from the second portion 110B of the interior volume 110. Furthermore, in some embodiments, the second support 112 can form the bottom of the chamber body 102.

The gas supply system 130 includes a first gas distributor 131, a second gas distributor 132, gas lines 133, and a gas source 134. The gas lines 133 connect the gas source 134 to the first gas distributor 131 and the second gas distributor 132. The first gas distributor 131 is located over the first plurality of standoffs 121 in the first portion 110A of the interior volume 110. The second gas distributor 132 is located over the second plurality of standoffs 122 in the second portion 110B of the interior volume 110. In one embodiment, the gas source 134 is configured to provide one or more gases, such as inert gases (e.g., argon) as well as other gases (e.g., nitrogen or clean dry air).

The vacuum exhaust system 170 includes a first exhaust line 171, a second exhaust line 172, a main exhaust line 173, and a vacuum pump 175. The first exhaust line 171 is fluidly coupled to the first portion 110A of the interior volume 110 at a first exhaust inlet 141 of the load lock chamber 101. Similarly, the second exhaust line 172 is fluidly coupled to the second portion 110B of the interior volume 110 at a second exhaust inlet 142 of the load lock chamber 101. The main exhaust line 173 fluidly couples the first exhaust line 171 and the second exhaust line 172 to the vacuum pump 175. In some embodiments, which can be combined with other embodiments, the vacuum pump 175 can be configured to reduce the pressure in the first portion 110A and the second portion 110B of the interior volume 110 to pressures from about 10 mTorr to about 500 mTorr, such as from about 50 mTorr to about 300 m Torr, such as about 100 mTorr.

The first exhaust line 171 includes a first exhaust valve 161 that is configured to open when the vacuum pump 175 is reducing the pressure of the first portion 110A of the interior volume 110. A first heater jacket 165 is positioned around the first exhaust valve 161. The first heater jacket 165 includes one or more heaters 167 (e.g., resistive heaters) that are configured to heat the gases in the interior of the first exhaust line 171. In some embodiments, the one or more heaters 167 can be configured to heat the gas in the first exhaust line to a temperature from about 50° C. to about 80° C.

Similarly, the second exhaust line 172 includes a second exhaust valve 162 that is configured to open when the vacuum pump 175 is reducing the pressure of the second portion 110B of the interior volume 110. A second heater jacket 166 is positioned around the second exhaust valve 162. The second heater jacket 166 includes one or more heaters 167 (e.g., resistive heaters) that are configured to heat the gases in the interior of the second exhaust line 172.

The load lock chamber 101 further includes a first baffle 135 and a second baffle 136. The first baffle 135 is positioned in the first portion 110A of the interior volume 110 near the first exhaust inlet 141. The first baffle 135 can be horizontally spaced apart from the first exhaust inlet 141 by a distance from about 20 mm to about 250 mm, such as from about 40 mm to about 125 mm. The first baffle 135 is positioned between the first plurality of standoffs 121 (first substrate support) and the first exhaust inlet 141. In some embodiments, which can be combined with other embodiments, the first portion 110A of the interior volume 110 can include multiple exhaust inlets with a baffle positioned near each exhaust inlet with positioning similar to the position of the first baffle 135 relative to the first exhaust inlet 141.

The second baffle 136 is positioned in the second portion 110B of the interior volume 110 near the second exhaust inlet 142. The second baffle 136 can be horizontally spaced apart from the second exhaust inlet 142 by a distance from about X to about Y. The second baffle 136 is positioned between the second plurality of standoffs 122 (second substrate support) and the second exhaust inlet 142. In some embodiments, which can be combined with other embodiments, the second portion 110B of the interior volume 110 can include multiple exhaust inlets with a baffle positioned near each exhaust inlet with positioning similar to the position of the second baffle 136 relative to the second exhaust inlet 142.

The first baffle 135 and the second baffle 136 can be supported in their corresponding positions in a variety of ways. One example is shown in FIG. 1. In FIG. 1, the first baffle 135 is supported by a first baffle support 191 and the second baffle 136 is supported by a second baffle support 192. The first baffle support 191 includes an interior portion 195 and lateral supports 196. In one embodiment, the interior portion 195 has a ringed-shape structure and the lateral supports 196 are rods. The interior portion 195 is coupled to (e.g., fixed to) an interior wall of the first exhaust line 171. The lateral supports 196 extend from the interior portion 195 inside the first exhaust line 171 to the first baffle 135 located in the first portion 110A of the interior volume 110. Each lateral support 196 can be fixed (e.g., welded or fastened) to the interior portion 195 at a first end of the lateral support 196 and fixed (e.g., welded or fastened) to the first baffle 135 at an opposing second end of the lateral support 196.

Similarly, the second baffle support 192 includes an interior portion 195 and lateral supports 196. In one embodiment, the interior portion 195 has a ringed-shape structure and the lateral supports 196 are rods. The interior portion 195 is coupled to (e.g., fixed to) an interior wall of the second exhaust line 172. The lateral supports 196 extend from the interior portion 195 inside the second exhaust line 172 to the second baffle 136 located in the second portion 110B of the interior volume 110. Each lateral support 196 can be fixed (e.g., welded or fastened) to the interior portion 195 at a first end of the lateral support 196 and fixed (e.g., welded or fastened) to the second baffle 136 at an opposing second end of the lateral support 196.

The processing system 100 also includes the controller 185 for controlling processes performed by the processing system 100. The controller 185 can be any type of controller used in an industrial setting, such as a programmable logic controller (PLC). The controller 185 includes a processor 187, a memory 186, and input/output (I/O) circuits 188. The controller 185 can further include one or more of the following components (not shown), such as one or more power supplies, clocks, communication components (e.g., network interface card), and user interfaces typically found in controllers for semiconductor equipment.

The memory 186 can include non-transitory memory. The non-transitory memory can be used to store the programs and settings described below. The memory 186 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

The processor 187 is configured to execute various programs stored in the memory 186, such as programs for controlling the pressure in the first portion 110A and the second portion 110B of the interior volume 110 of the load lock chamber 101. During execution of these programs, the controller 185 can communicate to I/O devices through the I/O circuits 188. For example, during execution of these programs and communication through the I/O circuits 188, the controller 185 can control outputs, such as changing the position of valves (not shown) to send different gases to the interior volume 110 of the load lock chamber 101, and the controller 185 can adjust the speed of the vacuum pump 175 to adjust the pressure in the interior volume 110. The memory 186 can further include various operational settings used to control the processing system 100. For example, the settings can include pressure settings at which the controller 185 can use for controlling the pressure in the first portion 110A and the second portion 110B of the interior volume 110. The controller 185 can use the pressure settings along with measurements from one or more pressure sensors (not shown) to adjust the speed of the vacuum pump 175.

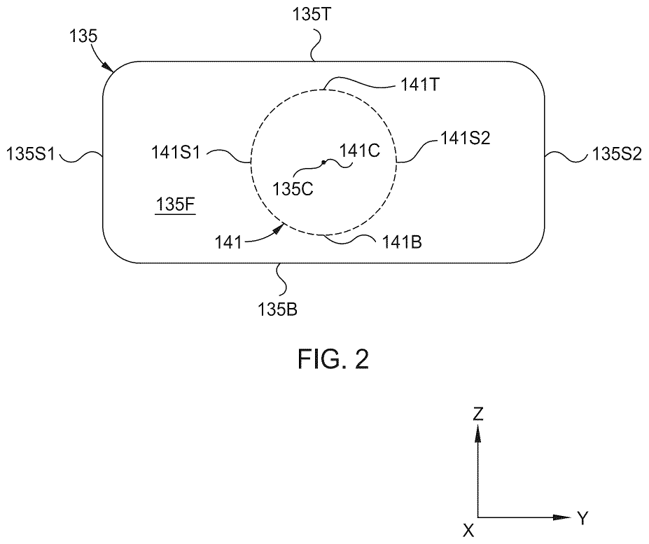

FIG. 2 shows a front view of a front surface 135F of the first baffle 135 from FIG. 1, according to one embodiment. The first exhaust inlet 141 is shown with a dashed line to indicate that the first exhaust inlet 141 is hidden behind the first baffle 135. The second baffle 136 is positioned in a similar arrangement relative to the second exhaust inlet 142 as the first baffle 135 is positioned relative to the first exhaust inlet 141. Thus, the following description of the first baffle 135 and the first exhaust inlet 141 also applies in a corresponding manner to the second baffle 136 and the second exhaust inlet 142.

The front surface 135F of the first baffle 135 covers a larger area in the YZ plane of the front surface 135F than the area that first exhaust inlet 141 covers in the corresponding YZ plane of the first exhaust inlet 141. Although the first baffle 135 is spaced apart from the first exhaust inlet 141 in the X-direction (see FIG. 1), the first baffle 135 extends further in the Y-direction and the Z-direction than the first exhaust inlet 141. For example, (1) a top 135T of the first baffle 135 is positioned above a top 141T of the first exhaust inlet 141, (2) a bottom 135B of the first baffle 135 is positioned below a bottom 141B of the first exhaust inlet 141, (3) a first side 135S1 of the first baffle 135 is positioned further in the negative Y-direction (i.e., further to the left in FIG. 2) than a corresponding first side 141S1 of the first exhaust inlet 141, and (4) a second side 135S2 of the first baffle 135 is positioned further in the positive Y-direction (i.e., further to the right in FIG. 2) than a corresponding second side 141S2 of the first exhaust inlet 141. In some embodiments, which can be combined with other embodiments, a center 135C of the first baffle 135 can be aligned with a center 141C of the first exhaust inlet 141.

Positioning the first baffle 135 in front of the first exhaust inlet 141 and having the first baffle 135 extend further than the first exhaust inlet 141 in all directions that are perpendicular to the X-direction (i.e., the Y and Z-directions) enables the first baffle 135 to cause a significant portion of the gas in in the first portion 110A of the interior volume 110 to be redirected around the first baffle 135 before entering the first exhaust inlet 141. This redirection makes the pressure in the first portion 110A of the interior volume 110 and in the first exhaust line 171 more uniform when compared to otherwise similar equipment without the first baffle 135 when the vacuum pump 175 reduces the pressure in the first portion 110A of the interior volume 110 to the target pressure. This improved pressure uniformity reduces and/or prevents occurrences of extreme low pressure and rapidly decreasing pressure as the vacuum pump 175 reduces the pressure in the first portion 110A of the interior volume 110. Extreme low pressures and rapidly decreasing pressure can cause the most condensation inside the load lock chambers and exhaust lines.

With reference to FIG. 1 and FIG. 2, the top 135T of the first baffle 135 is also positioned above a top surface 51 of the substrate 50 and above the substrate supporting surface 121S of the first plurality of standoffs 121. Positioning the top 135T of the first baffle 135 above the top surface 51 of the substrate 50 and above the substrate supporting surface 121S of the first plurality of standoffs 121 causes a significant portion of the gas overlying the substrate 50 to be redirected around the first baffle 135 as this gas flows into the first exhaust inlet 141.

Similarly, the bottom 135B of the first baffle 135 is positioned below a bottom surface 52 of the substrate 50 and below the substrate supporting surface 121S of the first plurality of standoffs 121. Positioning the bottom 135B of the first baffle 135 below the bottom surface 52 of the substrate 50 and below the substrate supporting surface 121S of the first plurality of standoffs 121 causes a significant portion of the gas underlying the substrate 50 to be redirected around the first baffle 135 as this gas flows into the first exhaust inlet 141. This redirection makes the pressure in the first portion 110A of the interior volume 110 and in the first exhaust line 171 more uniform when compared to otherwise similar equipment without the first baffle 135. This improved pressure uniformity reduces and/or prevents instances of extreme low pressure, which cause the most condensation inside the load lock chambers and exhaust lines.

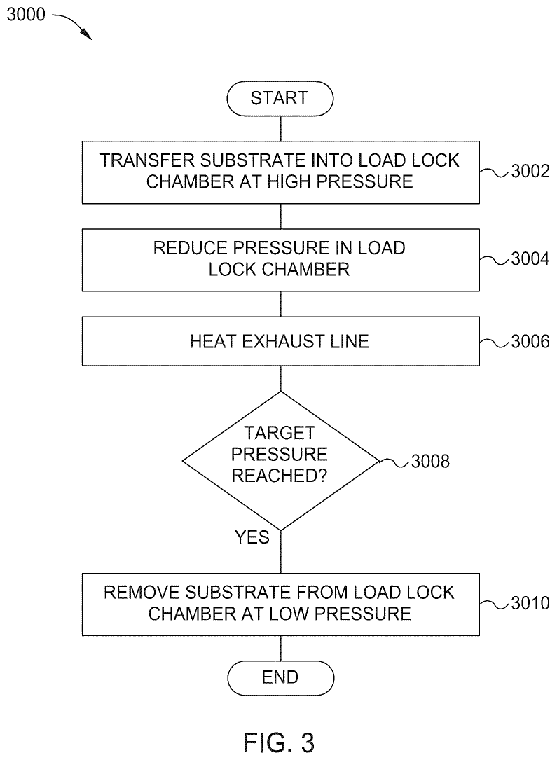

FIG. 3 is a process flow diagram of a method 3000 of transferring a substrate 50 through the load lock chamber 101 of FIG. 1 using the processing system 100 of FIG. 1, according to one embodiment. The method 3000 can be performed by the controller 185 in communication with various inputs (e.g., sensors) and outputs (e.g., valves and motors). With reference to FIGS. 1, 2, and 3, the method 3000 is described. The method 3000 is mainly described in reference to moving a substrate 50 through the first portion 110A of the interior volume 110, but this description is also applicable to moving a substrate 50 through the second portion 110B of the interior volume 110 using the corresponding equipment in or connected to the second portion 110B of the interior volume 110 of the load lock chamber 101.

The method begins at block 3002. At block 3002, a substrate 50 is transferred into the first portion 110A of the interior volume 110 of the load lock chamber 101 when the first portion 110A is at a higher pressure, such as atmospheric pressure. The environment of the first portion 110A of the interior volume can include gases from the ambient environment including water vapor. The substrate 50 can be positioned on the first plurality of standoffs 121 (first substrate support).

At block 3004, the pressure in the first portion 110A of the interior volume 110 is reduced to a vacuum pressure such as a pressure from about 10 mTorr to about 500 mTorr, such as from about 50 mTorr to about 300 m Torr, such as about 100 mTorr. The first exhaust valve 161 can be opened by the controller 185 and the vacuum pump 175 can be activated by the controller 185 to reduce the pressure in first portion 110A of the interior volume to a target vacuum pressure.

In some embodiments, which can be combined with other embodiments, the speed of the vacuum pump 175 can be gradually ramped up to a target speed (e.g., over a duration, such as 5 seconds or 15 seconds) to reduce the occurrences of having of areas of extreme low pressure that can lead to condensation of water vapor in the gas being exhausted from the first portion 110A of the interior volume 110. The first baffle 135 further aids in improving the uniformity of pressure in the first portion 110A of the interior volume 110 and the first exhaust line 171 when the vacuum pump 175 is activated to reduce the pressure in the first portion 110A of the interior volume 110.

In some embodiments, which can be combined with other embodiments, the pressure in the first portion 110A of the interior volume 110 can be stepped down to the target pressure using a series of two or more pump and purge cycles. The gas provided to the interior volume 110 from the gas source 134 is generally free of water vapor. Thus, in some embodiments, gas, such as inert gas, can be provided to the first portion 110A of the interior volume 110 while exhausting gas from the first portion 110A of the interior volume 110 but without significantly reducing the pressure in the interior volume 110. This process purges water vapor from the first portion 110A of the interior volume without having the pressure drop that can lead to condensation. The concentration of water vapor has a direct relationship to the amount of condensation of water vapor occurring in an environment. Thus, using the gas from the gas source 134 to reduce the concentration of water vapor before the pressure in the first portion 110A of the interior volume is significantly reduced (e.g., reducing from atmospheric pressure to 100 m Torr) can significantly reduce the amount of condensation occurring inside a load lock chamber and exhaust lines connected to the load lock chamber. In some embodiments, which can be combined with other embodiments, the first portion 110A of the interior volume 110 is purged with the gas from the gas source 134 before the vacuum pump 175 begins to significantly reduce (e.g., a reduction of 5% or more) the pressure in the first portion 110A of the interior volume 110, so that the water vapor concentration in the first portion 110A is reduced before the pressure in the first portion 110A is reduced.

During block 3004, gas can be supplied to the first portion 110A of the interior volume 110 from the gas source 134. The gas from the gas source 134 can be an inert gas (e.g., argon) as well as other gases (e.g., nitrogen or clean dry air). The gas from the gas source 134 can flow from the gas source 134, through the gas lines 133, and into the first portion 110A of the interior volume 110 through the first gas distributor 131. The gas from the gas source 134 is typically free of water vapor to reduce the concentration of water vapor in the first portion 110A of the interior volume 110.

At block 3006, the heater 167 in the first heater jacket 165 is energized to heat the gas flowing through the first exhaust line 171. Block 3006 can be executed before the start of, after the start of, or simultaneously with block 3004.

The heat provided by the heater 167 can reduce the amount of condensation occurring in the first exhaust line 171. This reduced condensation reduces the number of large particles in the first exhaust line 171 since the condensation can lead to smaller particles combining to form larger particles. Some of the particles in the first exhaust line 171 can eventually find their way to the interior volume 110 of the load lock chamber 101. Therefore, the reduction of condensation in the first exhaust line 171 caused by the heat provided by the heater 167 leads to less particles in the first portion 110A of the interior volume 110, which in turn leads to less particles, especially less larger particles, landing on substrates 50 in the first portion 110A of the interior volume 110. Less particles landing on substrates leads to higher product quality when compared to substrates that are exposed to environments in load lock chambers with higher particle levels, especially higher levels of large particles.

At block 3008, the controller 185 monitors the pressure in the first portion 110A of the interior volume 110 using one or more pressure sensors (not shown) to determine when a target pressure in the first portion 110A of the interior volume 110 is achieved.

After the controller 185 determines that the target pressure is reached, then the method 3000 can proceed to block 3010.

At block 3010, after the target vacuum pressure is reached, then the substrate 50 is removed from the first portion 110A of the interior volume 110 of the load lock chamber 101, so that the substrate 50 can be further processed in other equipment operating in a vacuum environment.

What is claimed is:

1. A system for transferring a substrate from a high pressure area to a low pressure area, the system comprising:
a load lock chamber comprising:
a chamber body disposed around an interior volume;
a first substrate support;
a first exhaust inlet; and
a first baffle positioned between the first substrate support and the first exhaust inlet; and
a first exhaust line fluidly coupled to the interior volume through the first exhaust inlet.

2. The system of claim 1, wherein
a top of the first baffle is positioned above a top of the first exhaust inlet, and
a bottom of the first baffle is positioned below a bottom of the first exhaust inlet.

3. The system of claim 1, wherein a horizontal distance between the first baffle and the first exhaust inlet is from about 40 mm to about 125 mm.

4. The system of claim 1, wherein
a top of the first baffle is positioned above a substrate supporting surface of the first substrate support, and
a bottom of the first baffle is positioned below the substrate supporting surface of the first substrate support.

5. The system of claim 1, wherein a front surface of the first baffle extends across a larger area than an area of the first exhaust inlet.

6. The system of claim 1, wherein
the first baffle is spaced from the first exhaust inlet in a first direction, and
the first baffle extends further than the first exhaust inlet in all directions that are perpendicular to the first direction.

7. The system of claim 1, further comprising a heater configured to heat gas in the first exhaust line.

8. The system of claim 7, wherein
the first exhaust line includes a valve and a heater jacket positioned around the valve, and
the heater jacket includes the heater.

9. A system for transferring a substrate from a high pressure area to a low pressure area, the system comprising:
a load lock chamber comprising:
a chamber body disposed around an interior volume;
a first substrate support;
a first exhaust inlet; and
a first baffle positioned in the interior volume, the first baffle configured to redirect a gas flow into the first exhaust inlet;
a first exhaust line fluidly coupled to the interior volume through the first exhaust inlet;
a vacuum pump fluidly coupled to the first exhaust line;
a heater configured to heat gas in the first exhaust line; and
a controller configured to activate the heater to heat gas in the first exhaust line when the vacuum pump is reducing a pressure of the interior volume.

10. The system of claim 9, wherein
the first exhaust line includes a valve and a heater jacket positioned around the valve, and
the heater jacket includes the heater.

11. The system of claim 9, wherein
a top of the first baffle is positioned above a top of the first exhaust inlet, and
a bottom of the first baffle is positioned below a bottom of the first exhaust inlet.

12. The system of claim 9, wherein a horizontal distance between the first baffle and the first exhaust inlet is from about 40 mm to about 125 mm.

13. The system of claim 9, wherein
a top of the first baffle is positioned above a substrate supporting surface of the first substrate support, and
a bottom of the first baffle is positioned below the substrate supporting surface of the first substrate support.

14. The system of claim 9, wherein a front surface of the first baffle extends across a larger area than an area of the first exhaust inlet.

15. The system of claim 9, wherein
the first baffle is spaced from the first exhaust inlet in a first direction, and
the first baffle extends further than the first exhaust inlet in all directions that are perpendicular to the first direction.

16. A method of moving a substrate from a high pressure environment to a low pressure environment, the method comprising:
transferring a substrate into an interior volume of a load lock chamber when the interior volume of the load lock chamber is at a first pressure, wherein
the substrate is positioned on a first substrate support in the interior volume, and
a first exhaust line is fluidly coupled to the interior volume through a first exhaust inlet of the load lock chamber;
reducing a pressure in the interior volume to a second pressure that is lower than the first pressure by exhausting gas from the interior volume through the first exhaust line when the substrate is positioned on the substrate support in the interior volume, the load lock chamber including a first baffle positioned between the first substrate support and the first exhaust inlet, wherein the first baffle redirects a gas flow into the first exhaust inlet as the pressure in the interior volume is reduced from the first pressure to the second pressure; and
removing the substrate from the interior volume after the pressure of the interior volume is at the second pressure.

17. The method of claim 16, further comprising heating the gas in the first exhaust line as the pressure in the interior volume is being reduced from the first pressure to the second pressure.

18. The method of claim 16, wherein
a top of the first baffle is positioned above a top of the first exhaust inlet, and
a bottom of the first baffle is positioned below a bottom of the first exhaust inlet.

19. The method of claim 16, wherein
a top of the first baffle is positioned above a substrate supporting surface of the first substrate support, and
a bottom of the first baffle is positioned below the substrate supporting surface of the first substrate support.

20. The method of claim 16, wherein a front surface of the first baffle extends across a larger area than an area of the first exhaust inlet.
